(19) United States
(12) Patent Application Publication
(10) Pub. No.: US 2025/0382487 A1
(43) Pub. Date: Dec. 18, 2025

(54) CONDUCTIVE INK COMPOSITIONS COMPRISING GOLD COMPLEXES

(71) Applicant: ELECTRONINKS INCORPORATED, Austin, TX (US)

(72) Inventors: S. Brett WALKER, Austin, TX (US); Ayan MAITY, Austin, TX (US)

(73) Assignee: ELECTRONINKS INCORPORATED, Austin, TX (US)

(21) Appl. No.: 18/879,681

(22) PCT Filed: Jun. 29, 2023
(86) PCT No.: PCT/US2023/069332

§ 371 Date: Dec. 27, 2024

Related U.S. Application Data
(60) Provisional application No. 63/356,857, filed on Jun. 29, 2022.

(51) Int. Cl. C09D 11/52; B41M 7/00; C09D 11/033; C09D 11/037; C09D 11/322; C09D 11/36; H05K 1/09

(52) U.S. Cl. CPC C09D 11/52; B41M 7/009; C09D 11/033; C09D 11/037; C09D 11/322; C09D 11/36; H05K 1/092

(57) ABSTRACT

Conductive ink compositions comprising gold complexes are provided. Also provided are methods of preparing the conductive ink compositions, methods of forming conductive structures from the conductive ink compositions, and structures formed from the conductive ink compositions. The conductive ink compositions preferably comprise a gold metal, an organophosphite ligand, and a solvent and are preferably particle-free. The conductive ink compositions can be used to form conductive structures comprising gold, for example by inkjet or other printing methods, at temperatures of 400° C. or less. Such conductive structures can be formed on a variety of substrates.

### CROSS-REFERENCE TO RELATED APPLICATIONS

This application claims the benefit of U.S. Provisional Application No. 63/356,857, filed on Jun. 29, 2022, the disclosure of which is incorporated herein by reference in its entirety.

### FIELD OF THE INVENTION

The present disclosure relates generally to novel ink compositions comprising gold and their methods of preparation and use. More particularly, the present disclosure relates to particle-free conductive ink compositions comprising gold complexes, including inks prepared using novel gold organometallic complexes. The inks are particularly useful in inkjet printing, including aerosol jet machine printing applications.

### BACKGROUND OF THE INVENTION

The electronics, display, and energy industries rely on the production and use of coatings and patterns of conductive materials to form circuits on organic and inorganic substrates. Printed electronics offer an attractive alternative to conventional technologies by enabling the creation of large-area, flexible devices at low cost. There is a great need for high-conductivity materials with fine-scale features in modern electronics such as solar cell electrodes, flexible displays, radio frequency identification tags, antennas, and many more. In efforts to make these high-technology devices increasingly affordable, the substrates used typically have relatively little temperature resilience and require low processing temperatures to maintain integrity.

The vast majority of commercially produced conductive inks are specifically designed for inkjet, screen-printing, or roll-to-roll processing methods in order to process large areas with fine-scale features in short time periods. These inks have disparate viscosities and synthesis parameters. Particle-based inks are based on conductive metal particles, which are typically synthesized separately and then incorporated into an ink formulation. The resulting ink is then tuned for specific particle process.

Typically, precursor-based inks are based on thermally unstable precursor complexes that undergo reduction to a conductive metal upon heating. Prior particle- and precursor-based methods generally rely on high temperatures to form conductive coatings and thus may not be compatible with substrates that require low processing temperatures to maintain integrity. For example, particle- and precursor-based conductive ink compositions are available that decompose at temperatures near 150° C., yielding electrical conductivities approaching that of bulk metal. Unfortunately, even these temperatures render the ink incompatible with many plastic and paper substrates commonly used in flexible electronic and biomedical devices.

Particle-free conductive inks comprising gold(III) are described in PCT International Publication No. WO2019/028436A1.

Strong donor ligands such as phosphines or N-heterocyclic carbenes (NHCs) have been widely used to stabilize the gold(I) oxidation state for various purposes. Trivalent phosphines impart stability to the gold complexes through σ-donation and π-back donation. While gold(I) phosphine complexes can be highly stable, they are typically not considered suitable for conductive ink formulations due to their higher decomposition temperature requirements (>400° C.).

Accordingly, there remains a need for conductive ink compositions comprising gold that display improved properties. It is thus an object of the present invention to provide particle-free conductive gold ink compositions and methods for their preparation and use, in particular compositions that can form conductive structures at low temperatures.

### SUMMARY OF THE INVENTION

The instant disclosure addresses these and other considerations by providing in one aspect a particle-free conductive ink composition comprising a gold metal, an organophosphite ligand, and a solvent, wherein the particle-free conductive ink composition forms a conductive metallic film by curing at no more than 400° C.

In some aspects, the techniques described herein relate to a particle-free conductive ink composition, wherein the gold metal is a gold(I) metal ion.

In some aspects, the techniques described herein relate to a particle-free conductive ink composition, wherein the organophosphite ligand is a trialkylphosphite ligand or a triarylphosphite ligand.

In some aspects, the techniques described herein relate to a particle-free conductive ink composition, wherein the trialkylphosphite ligand is a trimethylphosphite ligand or a triethylphosphite ligand.

In some aspects, the techniques described herein relate to a particle-free conductive ink composition, wherein the solvent includes an aromatic solvent.

In some aspects, the techniques described herein relate to a particle-free conductive ink composition, wherein the aromatic solvent is anisole, toluene, or xylene.

In some aspects, the techniques described herein relate to a particle-free conductive ink composition, wherein the solvent includes a polar, aprotic solvent.

In some aspects, the techniques described herein relate to a particle-free conductive ink composition, wherein the solvent includes a cyclic ether solvent or an acyclic ether solvent.

In some aspects, the techniques described herein relate to a particle-free conductive ink composition, wherein the cyclic ether solvent is a furan.

In some aspects, the techniques described herein relate to a particle-free conductive ink composition, wherein the acyclic ether solvent is a glycol ether, a dialkyl ether, or an ester.

In some aspects, the techniques described herein relate to a particle-free conductive ink composition, wherein the solvent is tetrahydrofuran or dipropylene glycol methyl ether.

In some aspects, the techniques described herein relate to a particle-free conductive ink composition, further including a nitrile ligand.

In some aspects, the techniques described herein relate to a particle-free conductive ink composition, wherein the nitrile ligand is an alkylnitrile ligand.

In some aspects, the techniques described herein relate to a particle-free conductive ink composition, wherein the alkylnitrile ligand is acetonitrile, propionitrile, or butyronitrile.

In some aspects, the techniques described herein relate to a particle-free conductive ink composition, wherein the particle-free conductive ink composition further includes an oxidant.

In some aspects, the techniques described herein relate to a particle-free conductive ink composition, wherein the oxidant is a nitrate, a hexafluorophosphate, a tetrafluoroborate, a trifluoroacetate, or a perchlorate.

In some aspects, the techniques described herein relate to a particle-free conductive ink composition, wherein the nitrate is silver nitrate.

In some aspects, the techniques described herein relate to a particle-free conductive ink composition, wherein the gold metal is a gold(I) metal ion; the organophosphite ligand is a trialkylphosphite ligand; and the solvent includes an aromatic solvent or a polar, aprotic solvent.

In some aspects, the techniques described herein relate to a particle-free conductive ink composition, further including a nitrile ligand.

In some aspects, the techniques described herein relate to a particle-free conductive ink composition, further including an oxidant.

In some aspects, the techniques described herein relate to a particle-free conductive ink composition, wherein the particle-free conductive ink composition forms a conductive metallic film by curing at no more than 300° C.

In some aspects, the techniques described herein relate to a particle-free conductive ink composition, wherein the particle-free conductive ink composition has a viscosity of 0.8-1.3 centipoise at 22° C.

In some aspects, the techniques described herein relate to a particle-free conductive ink composition, wherein the conductive metallic film displays a conductivity of at least 1% bulk metal conductivity.

In some aspects, the techniques described herein relate to a method of forming a conductive film comprising the steps of applying any of the above-described compositions to a substrate; and curing the particle-free conductive ink composition at no more than 400° C. to form the conductive film.

In some aspects, the techniques described herein relate to a method, wherein the applying step is performed using a printer.

In some aspects, the techniques described herein relate to a method, wherein the printer is a jet printer.

In some aspects, the techniques described herein relate to a method, wherein the jet printer is an aerosol jet printer.

In some aspects, the techniques described herein relate to a method, wherein the curing step is at no more than 300° C.

In some aspects, the techniques described herein relate to a conductive film formed by applying the particle-free conductive ink composition to a substrate and curing the particle-free conductive ink composition at no more than 400° C. to form the conductive film.

In some aspects, the techniques described herein relate to a method of forming a conductive ink composition including the step of: dissolving a gold complex in a solvent to form a gold complex solution.

In some aspects, the techniques described herein relate to a method, wherein the gold complex is a gold(I) trimethylphosphite complex.

In some aspects, the techniques described herein relate to a method, wherein the solvent includes an aromatic solvent or a polar, aprotic solvent.

In some aspects, the techniques described herein relate to a method, wherein a nitrile ligand is added to the gold complex solution.

In some aspects, the techniques described herein relate to a method, wherein the nitrile ligand is an alkylnitrile ligand.

In some aspects, the techniques described herein relate to a method, wherein the alkylnitrile ligand is acetonitrile, propionitrile, or butyronitrile.

In some aspects, the techniques described herein relate to a method, wherein an oxidant is added to the gold complex solution.

In some aspects, the techniques described herein relate to a method, wherein the oxidant is a nitrate, a hexafluorophosphate, a tetrafluoroborate, a trifluoroacetate, or a perchlorate.

In some aspects, the techniques described herein relate to a method, wherein the nitrate is silver nitrate.

### BRIEF DESCRIPTION OF THE DRAWINGS

FIG. 1 shows an exemplary conductive pattern printed using a gold conductive ink composition of the disclosure.

FIG. 2 shows the bulk conductivities of multilayered conductive structures printed using two exemplary gold conductive ink compositions of the disclosure.

### DETAILED DESCRIPTION OF THE INVENTION

### Conductive Gold Ink Compositions

Gold (I) phosphine complexes are understood to be highly stable but are generally considered unsuitable for formulation in conductive ink compositions due to their high decomposition temperatures. The instant inventors have surprisingly discovered, however, that incorporation of oxygen into the phosphine ligand (for example by using a phosphite ligand) can result in an ink that cures at reasonably low temperatures while maintaining the required stability of the ink to survive harsh ultrasonication exposure used to create an ink stream in an aerosol jet printer.

Accordingly, the instant disclosure provides in one aspect particle-free conductive ink compositions comprising a gold metal, an organophosphite ligand, and a solvent. In preferred embodiments, the gold metal is a gold(I) metal ion.

In some embodiments, the organophosphite ligand is a trialkylphosphite ligand, for example a trimethylphosphite ligand or a triethylphosphite ligand, although other organophosphite ligands may find utility in the conductive ink compositions of the disclosure.

In some embodiments, the conductive ink composition further comprises a nitrile ligand. More specifically, the nitrile ligand can be an alkylnitrile ligand such as, for example, acetonitrile, propionitrile, butyronitrile, or the like.

In some embodiments, the conductive ink composition further comprises an oxidant. More specifically, the oxidant can be a nitrate, such as, for example, a silver nitrate, a hexafluorophosphate, a tetrafluoroborate, a trifluoroacetate, or a perchlorate.

The solvent of the instant conductive ink compositions can be any solvent capable of completely, or nearly completely, dissolving the gold metal complexe. The solvent is also chosen for compatibility with the patterning technique to be used with the ink.

In some embodiments, the solvent comprises an aromatic solvent such as anisole, xylene, toluene or the like.

In some embodiments, the solvent comprises a polar, aprotic solvent. More specifically, the solvent can comprise a cyclic ether solvent or an acyclic ether solvent.

In more specific embodiments, the cyclic ether solvent can be a furan, such as tetrahyrofuran.

In other more specific embodiments, the acyclic ether solvent can be a glycol ether, a dialkyl ether, or an ester.

For example, the glycol ether can be ethylene glycol monomethyl ether (2-methoxyethanol, CH₃OCH₂CH₂OH), ethylene glycol monoethyl ether (2-ethoxyethanol, CH₃CH₂OCH₂CH₂OH), ethylene glycol monopropyl ether (2-propoxyethanol, CH₃CH₂CH₂OCH₂CH₂OH), ethylene glycol monoisopropyl ether (2-isopropoxyethanol, (CH₃)₂CHOCH₂CH₂OH), ethylene glycol monobutyl ether (2-butoxyethanol, CH₃CH₂CH₂CH₂OCH₂CH₂OH), ethylene glycol monophenyl ether (2-phenoxyethanol, C₆H₅OCH₂CH₂OH), ethylene glycol monobenzyl ether (2-benzyloxyethanol, C₆H₅CH₂OCH₂CH₂OH), propylene glycol methyl ether (1-methoxy-2-propanol, CH₃OCH₂CH(OH)CH₃), diethylene glycol monomethyl ether (2-(2-methoxyethoxy) ethanol, methyl carbitol, CH₃OCH₂CH₂OCH₂CH₂OH), diethylene glycol monoethyl ether (2-(2-ethoxyethoxy) ethanol, carbitol cellosolve, CH₃CH₂OCH₂CH₂OCH₂CH₂OH), diethylene glycol mono-n-butyl ether (2-(2-butoxyethoxy) ethanol, butyl carbitol, CH₃CH₂CH₂CH₂OCH₂CH₂OCH₂CH₂OH), dipropylene glycol methyl ether (CH₃O(CH₂CH(CH₃)O)₂H), or C12-15 pareth-12 (CH₃(CH₂)ₙ—(CH₂CH₂O)ₘ—H, where n=11-14 and m=12), which is also referred to as an ethoxylated C₁₂₋₁₅ alcohol.

For example, the dialkyl ether can be ethylene glycol dimethyl ether (dimethoxyethane, CH₃OCH₂CH₂OCH₃), ethylene glycol diethyl ether (diethoxyethane, CH₃CH₂OCH₂CH₂OCH₂CH₃), or ethylene glycol dibutyl ether (dibutoxyethane, CH₃CH₂CH₂CH₂OCH₂CH₂OCH₂CH₂CH₂CH₃).

For example, the ester can be ethylene glycol methyl ether acetate (2-methoxyethyl acetate, CH₃OCH₂CH₂OCOCH₃), ethylene glycol monoethyl ether acetate (2-ethoxyethyl acetate, CH₃CH₂OCH₂CH₂OCOCH₃), ethylene glycol monobutyl ether acetate (2-butoxyethyl acetate, CH₃CH₂CH₂CH₂OCH₂CH₂OCOCH₃), or propylene glycol methyl ether acetate (1-methoxy-2-propanol acetate).

The conductive ink compositions may possess low viscosity so that they are compatible with a broad range of patterning techniques, including slot die coating, spin coating, roll-to-roll printing, including gravure, flexography, rotary screen printing, screen-printing, aerosol jet printing, inkjet printing, airbrushing, Mayer rod coating, flood coating, 3D printing, and electrohydrodynamic printing. In particular, the inks are compatible with inkjet printing, dip coating, and spray coating. The patterned features can be highly conductive at room temperature and can achieve bulk conductivity upon decomposing at mild temperatures (e.g., in some cases at less than about 100° C.). Finally, the ink compositions can remain stable at room temperature for months without particle precipitation.

Accordingly, conductive ink compositions (also referred to as “conductive inks” or “inks”) have been created for printing highly conductive features at low temperatures. Such inks can be stable, particle-free, and suitable for a wide range of patterning techniques. In some embodiments, a “particle-free” ink is one that does not include any particles at a diameter of greater than about 10 nm. In some embodiments, a “particle-free” ink is one that has less than about 1% particles, preferably less than about 0.1% particles. Gold complexes are employed in the inks as a precursor material, which ultimately yields the gold in the conductive gold coatings, lines, or patterns of the structure formed in the printing process.

In one aspect, a conductive ink composition includes a gold complex formed as shown in the reaction below, where target compound 2 can be synthesized from commercially available precursor 1. The isolated gold complex 2 can be employed in particle-free ink formulations.

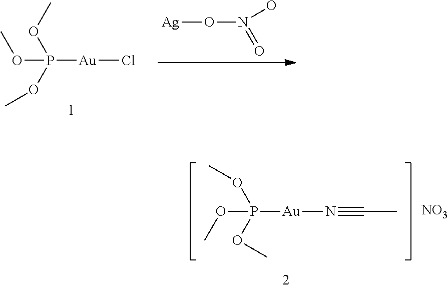

In some embodiments, the gold ink composition is configured for application to a substrate. In some embodiments, the gold ink composition can be converted to a conductive gold structure at a temperature of about 250° C. or less. In some embodiments, the gold ink composition can be converted to a conductive gold structure at a temperature of about 100° C. or less. In some embodiments, the gold ink composition can be converted to a conductive gold structure at a temperature of about 220° C. or less, of about 210° C. or less, of about 190° C. or less, of about 180° C. or less, of about 170° C. or less, of about 160° C. or less, of about 150° C. or less, of about 140° C. or less, of about 130° C. or less, of about 120° C. or less, of about 110° C. or less, of about 90° C. or less, of about 80° C. or less, of about 70° C. or less, of about 60° C. or less, or even of about 50° C. or less.

In some embodiments, the gold conductive ink composition has a concentration of about 1 to about 50 weight percent gold of the conductive ink composition. In some embodiments, the conductive ink composition has a concentration of about 1 to about 40 weight percent gold of the conductive ink composition. In some embodiments, the conductive ink composition has a concentration of about 1 to about 30 weight percent gold of the conductive ink composition. In some embodiments, the conductive ink composition has a concentration of about 1 to about 20 weight percent gold of the conductive ink composition. In some embodiments, the conductive ink composition has a concentration of about 1 to about 10 weight percent gold of the conductive ink composition. In some embodiments, the conductive ink composition has a concentration of about 5 to about 15 weight percent gold of the conductive ink composition. In some embodiments, the conductive ink composition has a concentration of about 1 weight percent, about 2 weight percent, about 3 weight percent, about 4 weight percent, about 5 weight percent, about 6 weight percent, about 7 weight percent, about 8 weight percent, about 9 weight percent, about 10 weight percent, about 11 weight percent, about 12 weight percent, about 13 weight percent, about 14 weight percent, about 15 weight percent, about 16 weight percent, about 17 weight percent, about 18 weight percent, about 19 weight percent, about 20 weight percent, about 21 weight percent, about 22 weight percent, about 23 weight percent, about 24 weight percent, about 25 weight percent, about 26 weight percent, about 27 weight percent, about 28 weight percent, about 29 weight percent, about 30 weight percent, about 31 weight percent, about 32 weight percent, about 33 weight percent, about 34 weight percent, about 35 weight percent, about 36 weight percent, about 37 weight percent, about 38 weight percent, about 39 weight percent, about 40 weight percent, about 41 weight percent, about 42 weight percent, about 43 weight percent, about 44 weight percent, about 45 weight percent, about 46 weight percent, about 47 weight percent, about 48 weight percent, about 49 weight percent, about 50 weight percent, or even higher weight percent gold in the conductive ink composition.

In some embodiments, the conductive ink compositions of the instant disclosure have a desired viscosity. In some embodiments, the desired viscosity is obtained using a micro VISC viscometer. In some embodiments, the viscosity is measured at room temperature, such as at, or about, 22° C. In some embodiments, the conductive ink composition has a viscosity from about 50 centipoise to about 1000 centipoise. In some embodiments, the conductive ink composition has a viscosity from about 0.5 centipoise to about 50 centipoise. In some embodiments, the conductive ink composition has a viscosity from about 1.0 centipoise to about 40 centipoise. In some embodiments, the conductive ink composition has a viscosity from about 2 centipoise to about 30 centipoise. In some embodiments, the conductive ink composition has a viscosity from about 0.5 centipoise to about 10 centipoise. In some embodiments, the conductive ink composition has a viscosity of about 1.0, about 2.0, or about 3.0 centipoise. In some embodiments, the conductive ink composition has a viscosity of at least about 0.5 centipoise, about 1.0 centipoise, about 2.0 centipoise, about 3.0 centipoise, about 4.0 centipoise, about 5.0 centipoise, about 6.0 centipoise, about 7.0 centipoise, about 8.0 centipoise, about 9.0 centipoise, about 10.0 centipoise, about 20.0 centipoise, about 30.0 centipoise, about 40.0 centipoise, about 50.0 centipoise, about 60.0 centipoise, about 70.0 centipoise, about 80.0 centipoise, or about 90.0 centipoise. In some embodiments, the conductive ink composition has a viscosity of at most about 100.0 centipoise, about 90.0 centipoise, about 80.0 centipoise, about 70.0 centipoise, about 60.0 centipoise, about 50.0 centipoise, about 40.0 centipoise, about 30.0 centipoise, about 20.0 centipoise, about 10.0 centipoise, about 9.0 centipoise, about 8.0 centipoise, about 7.0 centipoise, about 6.0 centipoise, about 5.0 centipoise, about 4.0 centipoise, about 3.0 centipoise, about 2.0 centipoise, or about 1.0 centipoise.

In some embodiments, the conductive ink composition has a viscosity of 0.8-1.3 centipoise at 22° C.

### Methods for Making Conductive Ink Compositions

According to another aspect, the disclosure provides methods for making a gold complex for use in a conductive ink composition, in particular a conductive ink composition as described above. These methods comprise the step of reacting a gold precursor complex, for example a reactive gold phosphite complex, with an oxidant, for example a silver salt such as silver nitrate. In some embodiments, the methods comprise the step of reacting a gold precursor complex, for example a reactive gold phosphite complex, with a nitrile ligand, for example an alkylnitrile ligand. In preferred embodiments, the gold precursor complex is reacted with both an oxidant and a nitrile ligand simultaneously. After the reaction, the gold complex is isolated and dissolved in a suitable solvent to form a particle-free conductive ink composition, for example, any of the conductive gold ink compositions described above.

### Methods for Forming a Conductive Structure

In another aspect are disclosed methods of making conductive structures. In some embodiments, the methods include the step of applying any of the above-described conductive ink compositions to a substrate. In some embodiments, the methods include the step of heating the conductive ink composition on the substrate at a decomposition temperature of about 250° C. or less to form the conductive structure. In some embodiments, the methods include the step of heating the conductive ink composition on the substrate at a decomposition temperature of about 210° C. or less, of about 200° C. or less, of about 190° C., of about 180° C. or less, of about 170° C. or less, of about 160° C., of about 150° C. or less, of about 140° C. or less, of about 130° C. or less, of about 120° C. or less, of about 110° C. or less, of about 90° C. or less, of about 80° C. or less, of about 70° C. or less, of about 60° C. or less, or of about 50° C. or less to form the conductive structure. In some embodiments, the conductive ink composition is heated with a heat source. Examples of heat sources include an IR lamp, oven, or a heated substrate.

In some embodiments, the electrical conductivity of the conductive structure formed from the conductive ink composition is measured. In some embodiments, the electrical conductivity of the conductive structure is from about 2×10⁻⁶ Ohm-cm to about 1×10⁻⁵ Ohm-cm. In some embodiments, the electrical conductivity of the conductive structure is from about 3×10⁻⁶ Ohm-cm to about 6×10⁻⁶ Ohm-cm. In some embodiments, the electrical conductivity of the conductive structure is at least about 2×10⁻⁶ Ohm-cm, about 3×10⁻⁶ Ohm-cm, about 4×10⁻⁶ Ohm-cm, about 5×10⁻⁶ Ohm-cm, about 6×10⁻⁶ Ohm-cm, about 7×10⁻⁶ Ohm-cm, about 8×10⁻⁶ Ohm-cm, or about 9×10⁻⁶ Ohm-cm. In some embodiments, the electrical conductivity of the conductive structure is at most about 1×10⁻⁵ Ohm-cm, about 9×10⁻⁶ Ohm-cm, about 8×10⁻⁶ Ohm-cm, about 7×10⁻⁶ Ohm-cm, about 6×10⁻⁶ Ohm-cm, about 5×10⁻⁶ Ohm-cm, about 4×10⁻⁶ Ohm-cm, or about 3×10⁻⁶ Ohm-cm.

The electrical conductivity of the conductive structure can in some embodiments be expressed in terms of sheet resistance (i.e., bulk resistivity divided by thickness) in units of ohms per square (also referred to as ohms/square or OPS). For example, in some embodiments, the resistance of the conductive structure is no more than 5 ohms per square, no more than 2 ohms per square, no more than 1 ohm per square, no more than 0.5 ohms per square, or even lower. Preferably, the resistance of the conductive structure is no more than 1 ohm per square.

The conductive ink compositions of the instant disclosure can be used to form conductive structures having high levels of bulk gold. Specifically, in some embodiments, the conductive structure has a bulk gold content of at least 1%. In more specific embodiments, the conductive structure has a bulk gold content of at least 2%, at least 5%, at least 10%, at least 15%, at least 20%, or even higher.

### Applications of the Conductive Ink Compositions

The conductive ink compositions of the instant disclosure can be used in various printing applications, including slot die coating, spin coating, roll-to-roll printing, including gravure, flexography, rotary screen printing, screen printing, aerosol jet printing, inkjet printing, airbrushing, Mayer rod coating, flood coating, 3D printing, dispenser, and electrohydrodynamic printing. In particular, the inks can be used in inkjet printing, dip coating, and spray coating.

Furthermore, patterns can be created using photolithography to create a mask to etch silver from certain areas, thereby creating high-fidelity features. Both positive and negative patterning processes may be used to create the patterns.

In some embodiments, the gold conductive ink composition is applied to a polymer substrate. In some embodiments, the gold conductive ink composition is applied to a nonpolar polymer substrate. In some embodiments, the gold conductive ink composition is applied to a glass substrate. In some embodiments, the gold conductive ink composition is applied to a ceramic substrate.

Furthermore, elastomers and 3D substrates with specifically non-planar topography can be used in conjunction with the conductive structures. In some embodiments, the gold conductive ink composition is applied to an elastomer. In some embodiments, the gold conductive ink composition is applied to a 3D substrate.

In some embodiments, the gold conductive ink composition of the instant methods has a concentration of about 0.1-50 weight percent gold complex of the ink composition. In some embodiments, the ink composition of the instant methods has a concentration of about 0.1-40 weight percent gold complex of the ink composition. In some embodiments, the ink composition has a concentration of about 1-30 weight percent gold complex of the ink composition. In some embodiments, the ink composition has a concentration of about 1-20 weight percent gold complex of the ink composition. In some embodiments, the ink composition has a concentration of about 1-10 weight percent gold complex of the ink composition. In some embodiments, the ink composition has a concentration of about 5-15 weight percent gold complex of the ink composition. In some embodiments, the ink composition has a concentration of about 0.1 weight percent, about 0.2 weight percent, about 0.3 weight percent, about 0.4 weight percent, about 0.5 weight percent, about 0.6 weight percent, about 0.7 weight percent, about 0.8 weight percent, about 0.9 weight percent, about 1 weight percent, about 2 weight percent, about 3 weight percent, about 4 weight percent, about 5 weight percent, about 6 weight percent, about 7 weight percent, about 8 weight percent, about 9 weight percent, about 10 weight percent, about 11 weight percent, about 12 weight percent, about 13 weight percent, about 14 weight percent, about 15 weight percent, about 16 weight percent, about 17 weight percent, about 18 weight percent, about 19 weight percent, or about 20 weight percent gold complex of the ink composition.

In some embodiments, the ink composition of the instant methods has a concentration of at least about 0.1 weight percent, about 0.2 weight percent, about 0.3 weight percent, about 0.4 weight percent, about 0.5 weight percent, about 0.6 weight percent, about 0.7 weight percent, about 0.8 weight percent, about 0.9 weight percent, 1 weight percent, about 2 weight percent, about 3 weight percent, about 4 weight percent, about 5 weight percent, about 6 weight percent, about 7 weight percent, about 8 weight percent, about 9 weight percent, about 10 weight percent, about 11 weight percent, about 12 weight percent, about 13 weight percent, about 14 weight percent, about 15 weight percent, about 16 weight percent, about 17 weight percent, about 18 weight percent, about 19 weight percent, or about 20 weight percent metal salt of the ink composition. In some embodiments, the ink composition has a concentration of at most about 40 weight percent, about 39 weight percent, about 38 weight percent, about 37 weight percent, about 36 weight percent, about 35 weight percent, about 34 weight percent, about 33 weight percent, about 32 weight percent, 31 weight percent, about 30 weight percent, about 29 weight percent, about 28 weight percent, about 27 weight percent, about 26 weight percent, about 25 weight percent, about 24 weight percent, about 23 weight percent, about 22 weight percent, about 21 weight percent, about 20 weight percent, about 19 weight percent, about 18 weight percent, about 17 weight percent, about 16 weight percent, about 15 weight percent, about 14 weight percent, about 13 weight percent, or about 12 weight percent gold complex of the ink composition.

In some embodiments, the ink composition of the instant methods has a concentration of about 0.1-50 weight percent gold complex of the ink composition. In some embodiments, the ink composition of the instant methods has a concentration of about 0.1-40 weight percent gold complex of the ink composition. In some embodiments, the ink composition has a concentration of about 1-30 weight percent gold complex of the ink composition. In some embodiments, the ink composition has a concentration of about 1-20 weight percent gold complex of the ink composition. In some embodiments, the ink composition has a concentration of about 1-10 weight percent gold complex of the ink composition. In some embodiments, the ink composition has a concentration of about 5-15 weight percent gold complex of the ink composition. In some embodiments, the ink composition has a concentration of about 0.1 weight percent, about 0.2 weight percent, about 0.3 weight percent, about 0.4 weight percent, about 0.5 weight percent, about 0.6 weight percent, about 0.7 weight percent, about 0.8 weight percent, about 0.9 weight percent, 1 weight percent, about 2 weight percent, about 3 weight percent, about 4 weight percent, about 5 weight percent, about 6 weight percent, about 7 weight percent, about 8 weight percent, about 9 weight percent, about 10 weight percent, about 11 weight percent, about 12 weight percent, about 13 weight percent, about 14 weight percent, about 15 weight percent, about 16 weight percent, about 17 weight percent, about 18 weight percent, about 19 weight percent, or about 20 weight percent gold complex of the ink composition.

### Decomposition

In another aspect, the gold conductive ink compositions of the disclosure are decomposed on a substrate to form a conductive structure on the substrate. In some embodiments, the gold conductive ink composition is decomposed by heating the composition at a temperature of about 270° C. or less. In some embodiments, the conductive ink composition is decomposed by heating the composition at a temperature of about 260° C. or less, about 250° C. or less, about 240° C. or less, about 230° C. or less, about 220° C. or less, about 210° C. or less, about 200° C. or less, about 190° C. or less, about 180° C. or less, about 170° C. or less, about 160° C. or less, about 150° C. or less, about 140° C. or less, about 130° C. or less, about 120° C. or less, about 110° C. or less, about 100° C. or less, about 90° C. or less, about 80° C. or less, or about 70° C. or less. In some embodiments, the conductive ink composition is heated by a heat source. Examples of heat sources include an IR lamp, oven, or a heated substrate.

In some embodiments, the conductive ink composition is decomposed by exposing the composition to a light source at a wavelength from about 100 nm to about 1500 nm. In some embodiments, the conductive ink composition is decomposed by exposing the composition to a light source such as a Xenon lamp or IR lamp at a wavelength from about 100 nm to about 1000 nm. In some embodiments, the conductive ink composition is decomposed by exposing the composition to a light source at a wavelength from about 100 nm to about 700 nm. In some embodiments, the conductive ink composition is decomposed by exposing the composition to a light source at a wavelength from about 100 nm to about 500 nm. In some embodiments, the conductive ink composition is decomposed by exposing the composition to a light source at a wavelength from about 100 nm to about 300 nm. In some embodiments, the conductive ink composition is decomposed by exposing the composition to a light source at a wavelength of about 100 nm, about 200 nm, about 300 nm, about 400 nm, about 500 nm, about 600 nm, about 700 nm, about 800 nm, about 900 nm, or about 1000 nm.

In some embodiments, the conductive ink composition is decomposed by a combination of heating the reducible metal complex, for example at any of the above-listed temperatures, and exposing the composition to a light source, for example at any of the above-listed wavelengths.

In some embodiments, the electrical conductivity of the conductive structures is measured. In some embodiments, the electrical conductivity of the conductive structures is about 1×10⁻⁶ Ohm-cm or greater. In some embodiments, the electrical conductivity of the conductive structures is from about 1×10⁻⁶ Ohm-cm to about 8×10⁻⁴ Ohm-cm. In some embodiments, the electrical conductivity of the conductive structures is from about 3×10⁻⁶ Ohm-cm to about 6×10⁻⁶ Ohm-cm. In some embodiments, the electrical conductivity of the conductive structures is at least about 1×10⁻⁶ Ohm-cm, about 2×10⁻⁶ Ohm-cm, about 3×10⁻⁶ Ohm-cm, about 4×10⁻⁶ Ohm-cm, about 5×10⁻⁶ Ohm-cm, about 6×10⁻⁶ Ohm-cm, about 7×10⁻⁶ Ohm-cm, about 8×10⁻⁶ Ohm-cm, about 9×10⁻⁶ Ohm-cm, about 1×10⁻⁵ Ohm-cm, about 2×10⁻⁵ Ohm-cm, about 3×10⁻⁵ Ohm-cm, about 4×10⁻⁵ Ohm-cm, about 5×10⁻⁵ Ohm-cm, about 6×10⁻⁵ Ohm-cm, about 7×10⁻⁵ Ohm-cm, about 8×10⁻⁵ Ohm-cm, about 9×10⁻⁵ Ohm-cm, about 1×10⁻⁴ Ohm-cm, about 2×10⁻⁴ Ohm-cm, about 3×10⁻⁴ Ohm-cm, about 4×10⁻⁴ Ohm-cm, about 5×10⁻⁴ Ohm-cm, about 6×10⁻⁴ Ohm-cm, or about 7×10⁻⁴ Ohm-cm. In some embodiments, the electrical conductivity of the conductive structures is at most about 8×10⁻⁴ Ohm-cm, 7×10⁻⁴ Ohm-cm, about 6×10⁻⁴ Ohm-cm, about 5×10⁻⁴ Ohm-cm, about 4×10⁻⁴ Ohm-cm, about 3×10⁻⁴ Ohm-cm, about 2×10⁻⁴ Ohm-cm, or about 1×10⁻⁴ Ohm-cm, about 9×10⁻⁵ Ohm-cm, about 8×10⁻⁵ Ohm-cm, about 7×10⁻⁵ Ohm-cm, about 6×10⁻⁵ Ohm-cm, about 5×10⁻⁵ Ohm-cm, about 4×10⁻⁵ Ohm-cm, about 3×10⁻⁵ Ohm-cm, about 2×10⁻⁵ Ohm-cm, about 1×10⁻⁵ Ohm-cm, about 9×10⁻⁶ Ohm-cm, about 8×10⁻⁶ Ohm-cm, about 7×10⁻⁶ Ohm-cm, about 6×10⁻⁶ Ohm-cm, about 5×10⁻⁶ Ohm-cm, about 4×10⁻⁶ Ohm-cm, about 3×10⁻⁶ Ohm-cm, or about 2×10⁻⁶ Ohm-cm.

### Applications of the Ink Compositions

The ink compositions of the instant disclosure can be used in various printing applications, including slot die coating, spin coating, roll-to-roll printing, including gravure, flexography, rotary screen printing, screen printing, aerosol jet printing, inkjet printing, airbrushing, Mayer rod coating, flood coating, 3D printing, and electrohydrodynamic painting. In particular, the inks can be used in inkjet printing, dip coating, and spray coating. Furthermore, patterns can be created using photolithography to create a mask to etch the gold from certain areas, thereby creating high-fidelity features.

In preferred embodiments, the ink compositions are used in aerosol jet printing applications to print conductive structures comprising gold metal. This method, which is also known as maskless mesoscale materials deposition or M3D (see, e.g., U.S. Pat. No. 7,485,345), involves atomization of the particle-free ink composition, via ultrasonic or pneumatic techniques, to generate droplets of micrometer scale. The aerosolized ink is combined with a carrier gas and directed via a flowhead onto a substrate where the ink is ultimately cured to a conductive structure.

In some embodiments, the ink compositions are compatible with many nonpolar polymer substrates, glasses, and ceramic substrates, where polar complexes do not wet particularly well. In some embodiments, the ink composition is applied to a polymer substrate. In some embodiments, the ink composition is applied to a nonpolar polymer substrate. In some embodiments, the ink composition is applied to a glass substrate. In some embodiments, the ink composition is applied to a ceramic substrate.

Furthermore, elastomers and 3D substrates with specifically non-planar topography can be used in conjunction with the conductive structures. In some embodiments, the ink composition is applied to an elastomer. In some embodiments, the ink composition is applied to a 3D substrate.

It will be readily apparent to one of ordinary skill in the relevant arts that other suitable modifications and adaptations to the compositions and methods described herein may be made without departing from the scope of the invention or any embodiment thereof. Having now described the present invention in detail, the same will be more clearly understood by reference to the following Examples, which are included herewith for purposes of illustration only and are not intended to be limiting of the invention.

### EXAMPLES

### Ink Formulations Comprising (Trimethylphosphite) Gold (I) Chloride and Their Curing Profiles

### Ink Formula 1

0.700 g (10 wt %) of (trimethylphosphite) gold(I) chloride was dissolved in 6.300 g (90 wt %) of anisole. The solution was stirred for 10 minutes. After complete precursor dissolution, a clear transparent ink solution was obtained with a viscosity of 1.2 centipoise and 3% solid content.

The ink solution was printed using the ultrasonic atomization setup with an Optomec aerosol jet printer. The platen temperature ranged from 25-50° C. to print four to six-layer structures. Two-centimeter by one-millimeter pads were printed on glass substrates for multiple hours without clogging or any change in ink appearance. The films were cured at 250° C. for 16 h. The conductivity obtained after curing at 250° C. are 8.9% bulk Au conductivity for four layers and 24.8% bulk Au conductivity for six layers.

### Ink Formula 2

0.300 g (30 wt %) of (trimethylphosphite) gold(I) chloride was dissolved in a mixture of 0.600 g (60 wt %) of tetrahydrofuran and 0.100 g (10 wt %) of dipropylene glycol methyl ether. The solution was stirred for 10 minutes. After complete precursor dissolution, a clear transparent ink solution was obtained.

The ink solution was printed using the ultrasonic atomization setup with an Optomec aerosol jet printer. The platen temperature was set to 80° C. to print increasing layers from one to three. Two-centimeter by one-millimeter pads were printed on glass substrates for multiple hours without clogging or any change in ink appearance. The films were cured at 240° C. for 1 h and additional 30 min at 300° C. The % bulk conductivities are 1.9% bulk Au for three layers at 240° C. and 2.4% bulk Au for one layer at 300° C. respectively.

### Synthesis of (acetonitrile)(trimethylphosphite)Gold(I) Nitrate (Target Compound 2)

A 100-mL round bottom flask was loaded with a stir bar. Into this, trimethylphosphite gold(I) chloride (2 g) was added under nitrogen followed by anhydrous tetrahydrofuran (31 mL). In a separate flask, AgNO₃ (0.953 g, 1 equivalent) was dissolved in dry acetonitrile (31 mL). AgNO₃ solution was added dropwise into the previous reaction mixture with constant stirring. A white precipitate was formed immediately. The reaction mixture was left stirring for 30 min. at room temperature under the exclusion of light. After the time period, the reaction mixture was filtered, and the volatiles were removed by rotary evaporation. The residue was triturated with pentane and finally the product was dried under high vacuum for 16 h.

Nuclear magnetic resonance spectroscopy of target compound 2 showed the presence of an inner-sphere acetonitrile molecule bound to gold. Without intending to be bound by theory, this binding is understood to stabilize the isolated complex in the presence of nitrate ion.

Ink Formulations with (Acetonitrile) (Trimethylphosphite) Gold(I) Nitrate and their Curing Profiles

### Ink Formula 3

In one embodiment, 2.449 g (22.8 wt %) of (acetonitrile) (trimethylphosphite) gold(I) nitrate was dissolved in a mixture of 6.347 g anisole (59.1 wt %), 1.944 g (18.1 wt %) of tetrahydrofuran. The solution was stirred for 10 minutes. After complete precursor dissolution, a clear transparent solution was obtained with a viscosity of 0.4 centipoise and 11% solid content.

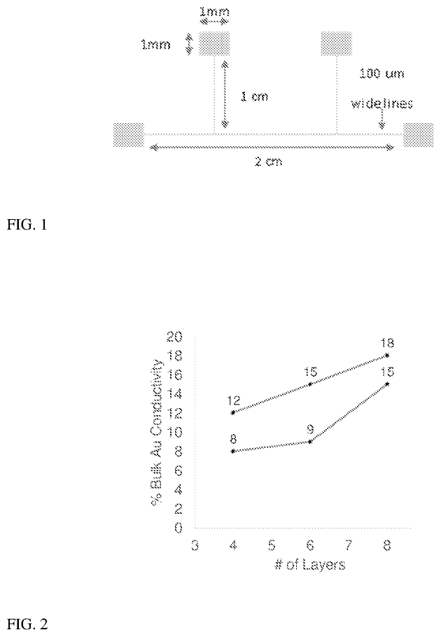

The ink was printed using an Optomec aerosol jet printer with the ultrasonication atomization attachment on a platen from 25-50° C. with increasing passes from four to eight layers. Regular wire and pads were printed on glass substrates for multiple hours without clogging or any change in ink appearance. An exemplary conductive pattern printed using this approach is illustrated in FIG. 1.

The film starts curing from 140° C. and lustrous gold color was visible. Further cured at elevated temperatures result in even higher conductivity. The printed wire-pad structures were annealed at 240° C. and 300° C. for 30 minutes. As shown in FIG. 2, conductivity obtained after curing at 240° C. ranges from 8-23% bulk Au (bottom line) while films cured at 300° C. ranges from 12-46% bulk Au (top line).

All patents, patent publications, and other published references mentioned herein are hereby incorporated by reference in their entireties as if each had been individually and specifically incorporated by reference herein.

While specific examples have been provided, the above description is illustrative and not restrictive. Any one or more of the features of the previously described embodiments can be combined in any manner with one or more features of any other embodiments in the present invention. Furthermore, many variations of the invention will become apparent to those skilled in the art upon review of the specification. The scope of the invention should, therefore, be determined by reference to the appended claims, along with their full scope of equivalents.

What is claimed is:

1. A particle-free conductive ink composition comprising:
a gold metal;
an organophosphite ligand; and
a solvent;
wherein the particle-free conductive ink composition forms a conductive metallic film by curing at no more than 400° C.

2. The particle-free conductive ink composition of claim 1, wherein the gold metal is a gold(I) metal ion.

3. The particle-free conductive ink composition of claim 1, wherein the organophosphite ligand is a trialkylphosphite ligand or a triarylphosphite ligand.

4. The particle-free conductive ink composition of claim 3, wherein the trialkylphosphite ligand is a trimethylphosphite or triethylphosphite ligand.

5. The particle-free conductive ink composition of claim 1, wherein the solvent comprises an aromatic solvent.

6. The particle-free conductive ink composition of claim 5, wherein the aromatic solvent is anisole, toluene, or xylene.

7. The particle-free conductive ink composition of claim 1, wherein the solvent comprises a polar, aprotic solvent.

8. The particle-free conductive ink composition of claim 7, wherein the solvent comprises a cyclic ether solvent or an acyclic ether solvent.

9. The particle-free conductive ink composition of claim 8, wherein the solvent comprises a cyclic ether solvent and an acyclic ether solvent.

10. The particle-free conductive ink composition of claim 8, wherein the cyclic ether solvent is a furan.

11. The particle-free conductive ink composition of claim 8, wherein the acyclic ether solvent is a glycol ether, a dialkyl ether, or an ester.

12. The particle-free conductive ink composition of claim 11, wherein the glycol ether is ethylene glycol monomethyl ether, ethylene glycol monoethyl ether, ethylene glycol monopropyl ether, ethylene glycol monoisopropyl ether, ethylene glycol monobutyl ether, ethylene glycol monophenyl ether, ethylene glycol monobenzyl ether, propylene glycol methyl ether, diethylene glycol monomethyl ether, diethylene glycol monoethyl ether, diethylene glycol mono-n-butyl ether, dipropylene glycol methyl ether, or an ethoxylated C₁₂₋₁₅ alcohol.

13. The particle-free conductive ink composition of claim 12, wherein the glycol ether is dipropylene glycol methyl ether.

14. The particle-free conductive ink composition of claim 11, wherein the dialkyl ether is ethylene glycol dimethyl ether, ethylene glycol diethyl ether, or ethylene glycol dibutyl ether.

15. The particle-free conductive ink composition of claim 11, wherein the ester is ethylene glycol methyl ether acetate, ethylene glycol monoethyl ether acetate, ethylene glycol monobutyl ether acetate, or propylene glycol methyl ether acetate.

16. The particle-free conductive ink composition of claim 1, further comprising a nitrile ligand.

17. The particle-free conductive ink composition of claim 16, wherein the nitrile ligand is an alkylnitrile ligand.

18. The particle-free conductive ink composition of claim 17, wherein the alkylnitrile ligand is acetonitrile, propionitrile, or butyronitrile.

19. The particle-free conductive ink composition of claim 16, wherein the particle-free conductive ink composition further comprises an oxidant.

20. The particle-free conductive ink composition of claim 19, wherein the oxidant is a nitrate, a hexafluorophosphate, a tetrafluoroborate, a trifluoroacetate, or a perchlorate.

21. The particle-free conductive ink composition of claim 20, wherein the nitrate is silver nitrate.

22. The particle-free conductive ink composition of claim 1, wherein
the gold metal is a gold(I) metal ion;
the organophosphite ligand is a trialkylphosphite ligand; and
the solvent comprises an aromatic solvent or a polar, aprotic solvent.

23. The particle-free conductive ink composition of claim 22, further comprising a nitrile ligand.

24. The particle-free conductive ink composition of claim 23, further comprising an oxidant.

25. The particle-free conductive ink composition of claim 1, wherein the particle-free conductive ink composition forms a conductive metallic film by curing at no more than 300° C.

26. The particle-free conductive ink composition of claim 1, wherein the composition has a viscosity of 0.8-1.3 centipoise at 22° C.

27. The particle-free conductive ink composition of claim 1, wherein the conductive metallic film displays a conductivity of at least 1% bulk metal conductivity.

28. A method of forming a conductive structure comprising the steps of:
applying the particle-free conductive ink composition of any one of claims 1-27 to a substrate; and
curing the particle-free conductive ink composition at no more than 400° C. to form the conductive structure.

29. The method of claim 28, wherein the step of applying is performed using a printer.

30. The method of claim 29, wherein the printer is a jet printer.

31. The method of claim 30, wherein the jet printer is an aerosol jet printer.

32. The method of claim 28, wherein the step of curing is at no more than 300° C.

33. A conductive structure formed by applying the particle-free conductive ink composition of any one of claims 1-27 to a substrate and curing the particle-free conductive ink composition at no more than 400° C. to form the conductive structure.

34. A method of forming a conductive ink composition comprising the step of:
dissolving a gold complex in a solvent to form a gold complex solution.

35. The method of claim 34, wherein the gold complex is a gold(I) trimethylphosphite complex or a gold(I) triethylphosphite complex.

36. The method of claim 34, wherein the solvent comprises an aromatic solvent or a polar, aprotic solvent.

37. The method of claim 34, further comprising the step of adding a nitrile ligand to the gold complex solution.

38. The method of claim 37, wherein the nitrile ligand is an alkylnitrile ligand.

39. The method of claim 38, wherein the alkylnitrile ligand is acetonitrile, propionitrile, or butyronitrile.

40. The method of claim 34, further comprising the step of adding an oxidant to the gold complex solution.

41. The method of claim 40, wherein the oxidant is a nitrate, a hexafluorophosphate, a tetrafluoroborate, a trifluoroacetate, or a perchlorate.

42. The method of claim 41, wherein the nitrate is silver nitrate.

43. The method of claim 34, further comprising the step of adding a nitrile ligand and an oxidant to the gold complex solution.
